(19) United States
(12) Patent Application Publication
(10) Pub. No.: US 2026/0304988 A1
(43) Pub. Date: Oct. 1, 2026

(54) METHOD FOR MANUFACTURING AN IMAGE SENSOR

(71) Applicant: Soitec, BERNIN (FR)

(72) Inventor: Sciancalepore Corrado, BERNIN (FR)

(21) Appl. No.: 19/144,643

(22) PCT Filed: Dec. 22, 2023
(86) PCT No.: PCT/FR2023/052105

§ 371 Date: Jun. 30, 2025

(30) Foreign Application Priority Data
Dec. 28, 2022 (FR) 2214569

(51) Int. Cl. H10F 39/00; H10F 39/18

(52) U.S. Cl. CPC H10F 39/807; H10F 39/014; H10F 39/182; H10F 39/184

(57) ABSTRACT

A method of manufacturing an image sensor for detecting visible light and short-wave infrared rays comprises: a. providing a carrier substrate comprising a first semiconductor material; b. forming, in the carrier substrate, cavities to define pixels sensitive to visible light in the first semiconductor material between the cavities; c. forming an electrically insulating protective layer at least on the lateral surfaces of each pixel sensitive to visible light; growing, in the cavities, a second semiconductor material that is different from the first semiconductor material, so as to form pixels sensitive to short-wave infrared rays.

### CROSS-REFERENCE TO RELATED APPLICATIONS

This application is a national phase entry under 35 U.S.C. § 371 of International Patent Application PCT/FR2023/052105, filed Dec. 22, 2023, designating the United States of America and published as International Patent Publication WO 2024/141738 A1 on Jul. 4, 2024, which claims the benefit under Article 8 of the Patent Cooperation Treaty of French Patent Application Serial No. FR2214569, filed Dec. 28, 2022.

### TECHNICAL FIELD

The present disclosure relates to a process for manufacturing an image sensor sensitive to visible light and to short-wave infrared rays.

### BACKGROUND

The manufacture of image sensors sensitive to visible light and to short-wave infrared (SWIR) rays involves using separate materials to form two different types of pixels: a first series of pixels sensitive to visible light, i.e., light the wavelength of which is between 380 and 780 nm, and a second series of pixels sensitive to short-wave infrared rays, i.e., rays the wavelengths of which extend from about 780 nm to about 3 μm.

Silicon is commonly used in the manufacture of sensors sensitive to visible light, for its semiconducting properties. In particular, use is made of silicon-on-insulator (SOI) substrates, which comprise: a doped silicon base substrate; an intermediate silicon-oxide layer, called the buried oxide layer; and a so-called active layer of silicon, which may be doped differently to the base substrate, and in which the pixels are formed.

However, silicon is not suitable for detecting infrared rays, the photon energy of which is too low to be detected by wide-bandgap materials such as silicon. Consequently, narrower bandgap materials, such as III-V semiconductors, which, for example, include alloys of indium phosphide (InP) or even alloys of germanium (Ge), are used to manufacture infrared cameras or sensors.

InP alloys are particularly used; however, InP is a relatively rare material that is only available in the form of substrates of small diameter (less than 15 cm), and it is brittle and relatively difficult to handle.

Consequently, in the prior art, manufacture of sensors sensitive simultaneously to visible light and to infrared rays requires use of a plurality of layers of different materials, originating from different substrates. The sensors obtained via this type of process typically comprise at least one silicon substrate, a layer of a semiconductor sensitive to visible light, and a layer of a different semiconductor, sensitive to infrared rays.

One alternative is to use III-V semiconductors to detect visible light but also infrared rays, as envisaged in document WO 2015/048304A2. In this type of sensor, as illustrated in FIG. 1, a layer 104 of indium-gallium arsenide (InGaAs) serves as a layer for detecting visible waves and short-wave infrared waves, the thickness of this layer being between 0.5 μm and 6 μm. The InGaAs layer 104 is formed by epitaxial growth on an InP substrate 101, and is covered with an additional InP layer 105 serving as contact layer. The surface layer 105 of indium phosphide is particularly thin, so as to allow visible light to reach the layer 104 of InGaAs.

However, the presence of the indium-phosphide layer 105 still decreases the quantum efficiency of the sensor at certain wavelengths of visible light, typically around 600 nm. Furthermore, using the same InGaAs layer 104 to detect visible and infrared waves means that the dimensions and spacing of the visible pixels must be the same as for the SWIR pixels. The resolution of the sensor is therefore limited by the resolution of the pixels sensitive to infrared rays, which is typically much lower than the resolution desired for the pixels sensitive to visible waves. This solution therefore does not allow a satisfactory resolution to be obtained for pixels sensitive to visible light.

### BRIEF SUMMARY

In order to overcome these drawbacks, the present disclosure provides a process for manufacturing an image sensor for detecting visible light and short-wave infrared rays, the process comprising the following steps:
a. providing a carrier substrate comprising a first semiconductor;
b. forming cavities in the carrier substrate in order to define pixels sensitive to visible light in the first semiconductor between the cavities;
c. forming an electrically insulating protective layer at least on the lateral surfaces of each pixel sensitive to visible light;
d. growing, in the cavities, a second material, different from the first material, so as to form pixels sensitive to short-wave infrared rays.

Thus, a sensor sensitive both to light rays in the visible spectrum and to short-wave infrared rays is obtained, the pixels sensitive to these two types of rays being located in the same plane, avoiding the need to stack successive semiconductor layers vertically. The sensor thus obtained exhibits no loss of quantum efficiency, and the resolution of its pixels sensitive to visible light rays is not limited by the resolution of its pixels sensitive to short-wave infrared rays.

According to one embodiment, the process comprises, between step a and step b, a step a′ of forming a protective film on the carrier substrate, to protect the pixels sensitive to visible light in step b of forming the cavities; and between step c and step d, a step c′ of removing the protective film in order to uncover the upper surface of the pixels sensitive to visible light.

According to one embodiment, the process comprises, between step a and step b, a step a′ of forming a protective film on the carrier substrate, to protect the pixels sensitive to visible light in step b of forming the cavities; and after step d, a step d′ of removing the protective film in order to uncover the upper surface of the pixels sensitive to visible light.

According to one embodiment, step c comprises forming the protective layer by rapid thermal annealing.

According to one embodiment, the first semiconductor is silicon.

According to one embodiment, the second semiconductor is a III-V semiconductor, preferably chosen from indium phosphide, indium-gallium arsenide, germanium alloys, or quantum dots, for example, colloidal quantum dots based on lead(II) sulfide.

According to one embodiment, the carrier substrate is a silicon-on-insulator substrate, and comprises in succession a base substrate, an electrically insulating intermediate layer and a single-crystal layer of the first semiconductor.

According to one embodiment, the process comprises, between step b and step c, a step b′ of thickening the single-crystal layer by homo-epitaxy.

According to one embodiment, step b is an etching step applied to the carrier substrate until the electrically insulating intermediate layer is reached.

According to one embodiment, the process comprises, after step c, and optionally step c′, a step c″ of removing, from the cavities, the material forming the electrically insulating intermediate layer, the pixels sensitive to short-wave infrared rays being formed, in step d, on the face of the base substrate revealed by the removing step c″.

According to one embodiment, the carrier substrate is a bulk substrate of the first semiconductor.

The present disclosure further provides an image sensor for detecting visible light and short-wave infrared rays, comprising:
a carrier substrate;
a plurality of pixels sensitive to visible light, which are formed in the carrier substrate, and pixels sensitive to short-wave infrared rays, the pixels sensitive to infrared rays being placed in a surface region of the carrier substrate;
a protective layer placed at least on the side walls of each pixel so as to electrically isolate each pixel from adjacent pixels;

the pixels forming an arrangement placed in the same plane, the carrier substrate being a semiconductor-on-insulator (SOI) substrate, especially silicon-on-insulator, the carrier substrate comprising in succession a base substrate made of a semiconductor, an electrically insulating intermediate layer and a single-crystal layer made of a semiconductor.

### BRIEF DESCRIPTION OF THE DRAWINGS

FIG. 1 illustrates a sensor sensitive to visible light and to short-wave infrared according to the prior art.

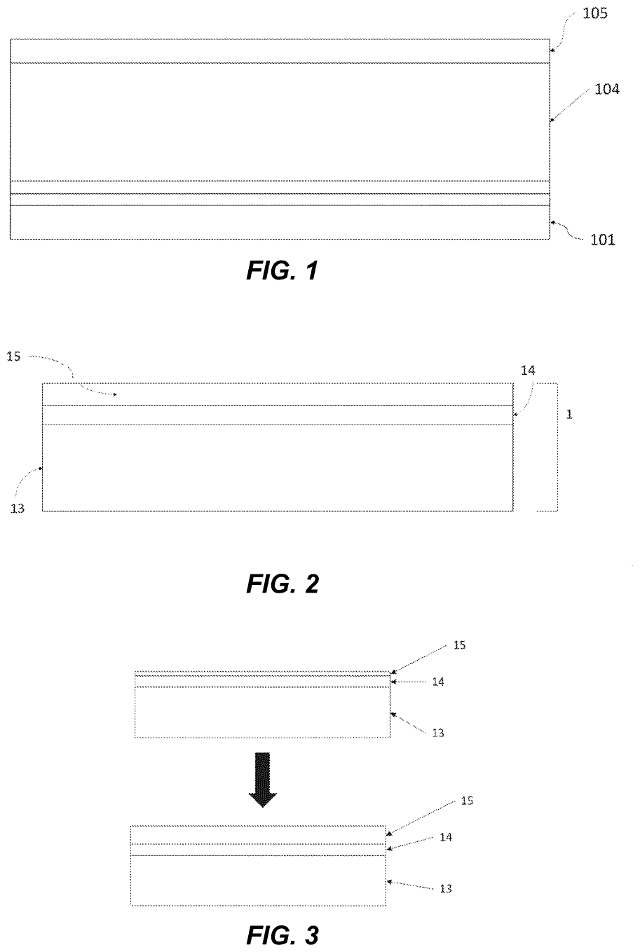

FIG. 2 illustrates a conventional SOI substrate.

FIG. 3 illustrates a step of epitaxial growth of the single-crystal layer of the SOI, according to one embodiment.

FIGS. 4A-4F illustrate the steps of the proposed process according to a first embodiment.

FIGS. 5A-5E illustrate the steps of the proposed process according to a second embodiment.

FIG. 6 shows an arrangement of pixels on a sensor, referred to as the “Bayer arrangement.”

For the sake of the legibility of the figures, the various elements are not necessarily shown to scale.

A given reference sign used in more than one figure designates the same element, which will not be described in detail more than once.

### DETAILED DESCRIPTION

The present disclosure relates to a process for manufacturing an image sensor capable of detecting visible light and short-wave infrared rays, and to sensors obtained through this process.

The process comprises a first step of providing a carrier substrate. This substrate comprises at least a first semiconductor, in which the pixels sensitive to visible light will be formed. More particularly, the first semiconductor may be silicon.

According to a first embodiment, the carrier substrate is a silicon-on-insulator (SOI) substrate, which comprises in succession a base substrate, an electrically insulating intermediate layer and a single-crystal layer of a first semiconductor.

If the single-crystal layer of the first semiconductor has a thickness less than the thickness desired for the pixels sensitive to visible light, the process may comprise a growth step aimed at thickening the layer. This step may be a step of epitaxial growth, and, in particular, of homo-epitaxy. For example, the thickness of the pixels sensitive to visible light is advantageously between 1 μm and 10 μm.

According to a second embodiment, the carrier substrate is formed wholly of the first semiconductor, and may, in particular, be a bulk silicon substrate.

The process comprises a step of forming cavities in the first semiconductor of the carrier substrate. This makes it possible to define, in the first semiconductor, between the cavities, a plurality of pixels sensitive to visible light. As will be seen below, the cavities will subsequently be filled with a second semiconductor sensitive to infrared rays. Consequently, the size of the cavities is advantageously chosen to optimize the size of the pixels sensitive to infrared rays and the distance between adjacent cavities is chosen to optimize the size of the pixels sensitive to visible light. For example, but non-limitingly, the distance between two adjacent cavities (corresponding substantially to the width of a pixel sensitive to visible light) is between 0.25 and 2 μm, and the width of the cavities (corresponding substantially to the width of a pixel sensitive to infrared rays) is between 1 and 10 μm.

Prior to this step of forming cavities, the proposed process may comprise a step of forming a protective film. Such a step aims to protect certain portions of the carrier substrate, and to leave other portions of the carrier substrate unprotected, the unprotected portions then forming the cavities. The step of forming cavities may be a plasma-assisted dry etching step.

The protective film may then, in particular, serve to protect certain portions of the carrier substrate during etching. It may, in particular, be a film that acts as a mask, protecting the carrier substrate from the etchant.

The protective film may be formed from silicon nitride, which has the advantage of having a high etching selectivity with respect to silicon and III-V materials.

After the cavities have been formed, the process further comprises a step of forming an electrically insulating protective layer on the pixels sensitive to visible light, and, in particular, on their lateral surfaces. When the bottom of the cavities is made of a semiconductor, the protective layer also extends over this surface. This layer may be obtained by rapid thermal annealing, in particular, in an oxidizing atmosphere.

The proposed process also comprises growth, in the cavities, of a second semiconductor different from the first semiconductor, the second semiconductor being sensitive to short-wave infrared rays. The second material is advantageously chosen from III-V semiconductors, such as alloys of indium phosphide (InP), of gallium-indium arsenide (InGaAs) or of germanium (Ge), or else formed from colloidal quantum dots such as colloidal quantum dots based on lead(II) sulfide or lead selenide.

The second semiconductor is grown heteroepitaxially on the first semiconductor. To this end, if the bottom of the cavities is covered with the electrically insulating protective layer, it is necessary beforehand to remove the layer to uncover the first semiconductor.

In order to grow the second semiconductor in the cavities, the surface of the pixels sensitive to visible light is advantageously protected by means of a mask, for example, one made of silicon nitride.

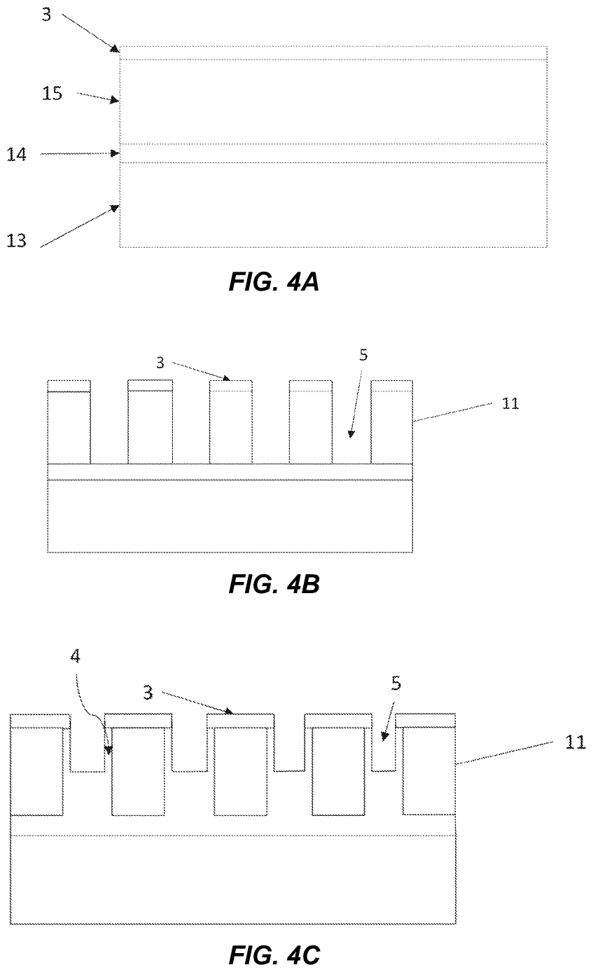

The first embodiment uses, as carrier substrate 1, an SOI, such as that shown in FIG. 2. Such an SOI comprises, in succession: a base substrate 13 made of semiconductor, generally silicon; an intermediate layer 14 made of electrically insulating material, in particular, silicon oxide; and a layer 15 made of single-crystal semiconductor, generally also silicon. The thickness of the single-crystal semiconductor layer is typically between 50 nm and a few μm.

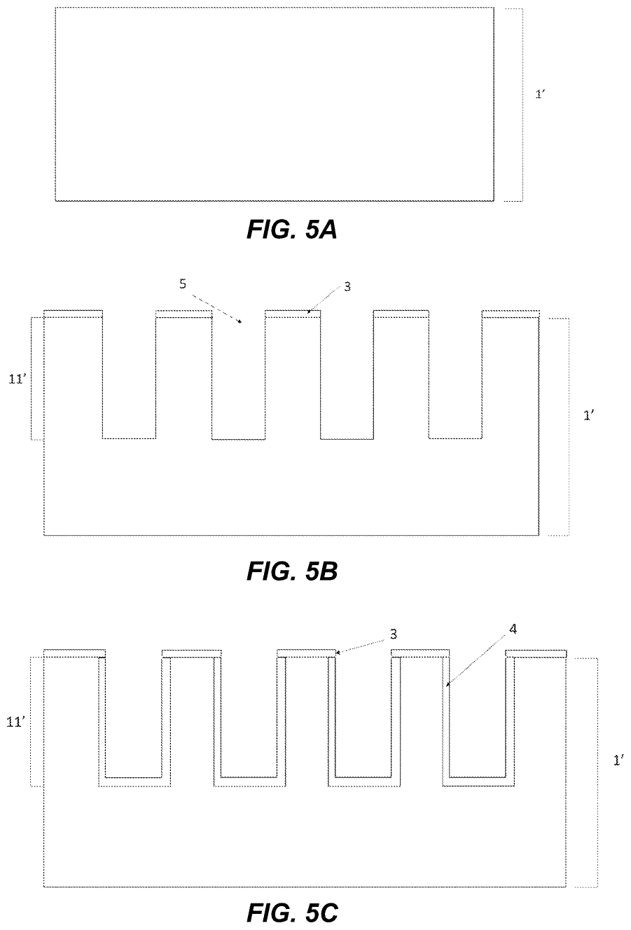

As illustrated in FIG. 4A, the proposed process may comprise a step of forming a protective film 3, which will selectively protect certain portions of the substrate 1 and leave other portions unprotected.

FIG. 4B shows a step of forming pixels 11 sensitive to visible light. In this step, cavities 5 are produced in the single-crystal layer 15 of the carrier substrate 1 until the insulating intermediate layer 14 is reached. According to one preferred embodiment, these cavities are produced by plasma-assisted dry etching, which is carried out in such a way as to etch the unprotected portions of the substrate 1, while the portions protected by the protective film 3 are not etched.

Such etching is generally anisotropic and essentially oriented in the thickness direction of the substrate 1, making it possible to obtain cavities 5 with sides substantially parallel to this direction.

The distance between the cavities, which corresponds substantially to the width of the portions of the carrier substrate 1 covered by the protective film 3, is chosen so as to obtain pixels 11 sensitive to visible light of a desired size.

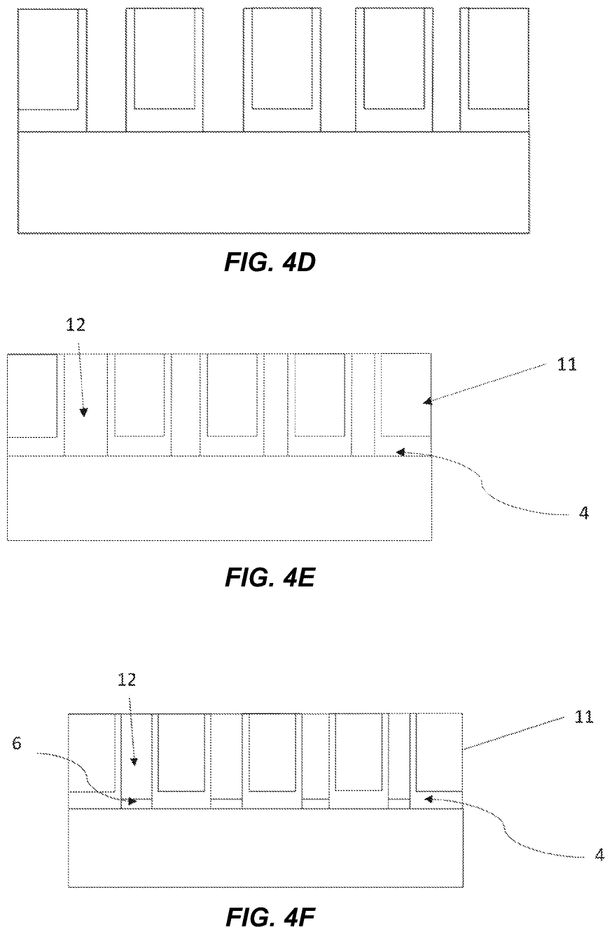

When the single-crystal layer 15 of the SOI is too thin to allow pixels 11 sensitive to visible light of the desired size to be formed, provision may be made for a step of epitaxial growth so as to thicken the single-crystal layer 15, for example, to a thickness on the order of a few microns. Such a step is illustrated in FIG. 3. Since this layer is preferably formed from silicon, this step will in this case be a step of homo-epitaxy of single-crystal silicon on the single-crystal layer 15.

This step, in particular, makes it possible to choose the thickness of the pixels 11 sensitive to visible light, this thickness depending directly on the thickness of the single-crystal layer 15 of the SOI.

As illustrated in FIG. 4C, once the cavities have been obtained, an electrically insulating protective layer 4 is formed so as to protect at least the side walls of each pixel sensitive to visible light. According to one embodiment, this protective layer is obtained by thermal oxidation, which may involve rapid thermal annealing. When such thermal annealing is carried out in an oxidizing atmosphere, a silicon-oxide layer forms on the surface of the pixels 11 sensitive to visible light, forming the protective layer 4. Moreover, the protective layer may also be formed by deposition. The function of this protective layer 4 is to create electrical insulation between the pixels 11 sensitive to visible light and the pixels 12 sensitive to short-wave infrared rays that will be formed in a subsequent step of the process.

Using an SOI as a carrier substrate thus makes it possible to obtain a silicon-oxide layer present both on the side walls of the pixels 11 sensitive to visible light and between these pixels and the base substrate 13 of the carrier substrate 1. Indeed, the protective silicon-oxide layer 4 is already partially formed by the intermediate layer 14 of the SOI serving as carrier substrate 1. This allows electrical insulation of the pixels 11 sensitive to visible light not only with respect to the pixels 12 sensitive to short-wave infrared, but also with respect to the rest of the carrier substrate 1, this limiting transconductance effects between pixels.

The process then comprises a step of removing the portions of the protective layer 4 (or 14) lying at the bottom of the cavities, so as to reveal the base substrate 13 of the carrier substrate 1 such as illustrated in FIG. 4D. The protective layer is then located only around the side walls of each pixel 11 sensitive to visible light, and between these pixels 11 and the base substrate 13 of the carrier substrate 1.

This makes it possible to reveal an upper surface of the carrier substrate 1, with a view to forming thereon the pixels 12 sensitive to infrared rays, as will be explained below.

Lastly, the process comprises a step of forming pixels 12 sensitive to infrared rays, on the portions of the carrier substrate 1 located between the pixels 11 sensitive to visible light. This step is illustrated in FIG. 4E. Preferably, this formation is carried out by epitaxy, a superficial surface of the carrier substrate 1 then serving as a seed layer for growth of the material sensitive to infrared rays. According to one embodiment, the material forming the pixels 12 is chosen from the III-V semiconductors, such as alloys of indium phosphide (InP), of gallium-indium arsenide (InGaAs) or of germanium (Ge). The material forming the pixels 12 may also be formed from colloidal quantum dots such as lead(II)-sulfide colloidal quantum dots. Since the substrate 1 is generally made of silicon, this step is preferably a step of hetero-epitaxial growth.

When a protective film 3 has been used to form the cavities 5, the film is removed following the step of forming pixels 12 sensitive to infrared rays. Thus, the protective film 3 also makes it possible to prevent growth of the material forming the pixels 12 on the pixels 11 sensitive to visible light. The protective film 3 may, in particular, be removed by means of an additional etching step.

Forming the pixels 12 sensitive to short-wave infrared rays in cavities 5 placed between the pixels 11 sensitive to visible light makes it possible to have these two types of pixels placed in the same plane of the sensor. Thus, formation of the sensor does not require vertical stacking of photosensitive materials configured to detect visible light and short-wave infrared radiation, respectively. Contrary to prior-art sensors, neither of the two materials used is therefore buried, and all the pixels are directly exposed to the light rays.

Thus, sensors obtained by means of the proposed process do not exhibit the loss of quantum efficiency observed in prior-art sensors at certain wavelengths.

Furthermore, since the formation of the pixels 12 sensitive to infrared rays is independent of the formation of the pixels 11 sensitive to visible light, these pixels 12 are formed with the desired dimensions (they, in particular, have the desired width and thickness), independently of the dimensions of the pixels 11 sensitive to visible light. Each type of pixel is formed in the most suitable material.

As illustrated in FIG. 4F, it is optionally possible, before the step of forming the pixels 12 sensitive to infrared rays, to make provision to form a buffer layer 6 on the portions of the carrier substrate 1 located at the bottom of the cavities 5, so as to absorb any dislocations generated by the process of epitaxial growth of the pixels 12.

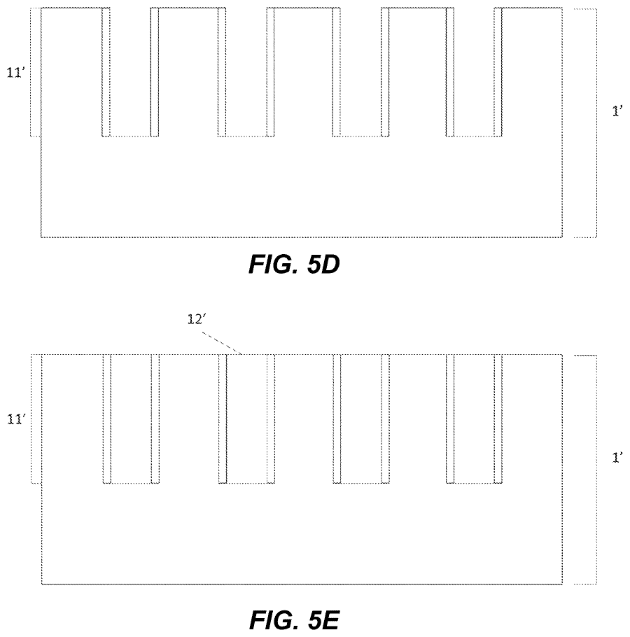

According to a second embodiment of the process, shown in FIGS. 5A-5E, a bulk silicon substrate is used as carrier substrate 1′, so as to obtain a sensor such as shown in FIG. 5E. According to this embodiment, and such as illustrated in FIG. 5B, cavities 5 are produced in the silicon layer 1′, preferably by etching using a protective film 3 such as described above. The cavities are produced in only one portion of the thickness of the carrier substrate 1′, so as to achieve a desired thickness of the pixels 11′ sensitive to visible light. A protective layer 4 is then formed, as shown in FIG. 5C. Next, provision may be made for a step of removing the portions of the protective layer 4 lying at the bottom of the cavities, so as to reveal the carrier substrate 1′. This step is shown in FIG. 5D.

In this embodiment, the protective layer 4 finally obtained will only be placed on the side walls of the pixels 11′ sensitive to visible light.

Lastly, the pixels 12′ sensitive to infrared rays are formed, in particular, by hetero-epitaxial growth on the superficial surface of the carrier substrate 1′ in the cavities 5. As in the preceding embodiment, a III-V semiconductor such as those mentioned above, or colloidal quantum dots such as lead(II)-sulfide colloidal quantum dots, will preferably be chosen as the material sensitive to infrared rays.

As in the preceding embodiment, when a protective film 3 has been used to form the cavities 5, the film is removed following the step of forming the pixels 12′ sensitive to infrared rays, in particular, by means of an additional etching step.

As described above, a buffer layer 6 may be provided between the carrier substrate 1′ and the material sensitive to infrared rays, so as to absorb any dislocations generated by the process of epitaxial growth of the pixels 12′.

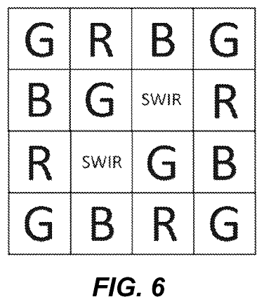

FIG. 6 illustrates, as seen from above, one example of arrangement of pixels of a sensor, in the form of a Bayer matrix comprising pixels sensitive to visible light of blue, green or red color (denoted R, G and B for red, green, blue, respectively) and pixels sensitive to short-wave infrared rays (denoted SWIR). All pixels are located in the same plane. The shape and size of the pixels are given merely by way of indication and are not representative of the actual size of the two types of pixels.

1. A method of manufacturing an image sensor for detecting visible light and short-wave infrared rays, comprising the following steps:
a. providing a carrier substrate comprising a first semiconductor material;
b. forming cavities in the carrier substrate to define pixels sensitive to visible light in the first semiconductor material between the cavities;
c. forming an electrically insulating protective layer at least on the lateral surfaces of each pixel sensitive to visible light; and
d. growing, in the cavities, a second semiconductor material, different from the first semiconductor material, so as to form pixels sensitive to short-wave infrared rays.

2. The method of claim 1, further comprising:
between step a and step b, a step a′ of forming a protective film on the carrier substrate to protect the pixels sensitive to visible light in step b of forming the cavities; and
after step d, a step d′ of removing the protective film to uncover the upper surface of the pixels sensitive to visible light.

3. The method of claim 2, wherein step c comprises forming the protective layer by thermal oxidation.

4. The method of claim 3, wherein the first semiconductor material is silicon.

5. The method of claim 4, wherein the second semiconductor material is a III-V semiconductor material, a germanium alloy, or colloidal quantum dots based on lead(II) sulfide or lead selenide.

6. The method of claim 5, wherein the carrier substrate is a silicon-on-insulator substrate, and comprises in succession a base substrate, an electrically insulating intermediate layer and a single-crystal layer of the first semiconductor material.

7. The method of claim 6, further comprising, between step b and step c, a step b′ of thickening the single-crystal layer by homo-epitaxy.

8. The method of claim 6, wherein step b comprises etching the carrier substrate until the electrically insulating intermediate layer is reached.

9. The method of claim 6, further comprising, after step c, a step c″ of removing, from the cavities, the material forming the electrically insulating intermediate layer, and in wherein the pixels sensitive to short-wave infrared rays are formed in step d on the face of the base substrate revealed by the removing step c″.

10. The method of claim 5, wherein the carrier substrate is a bulk substrate of the first semiconductor material.

11. An image sensor for detecting visible light and short-wave infrared rays, comprising:
a carrier substrate;
a plurality of pixels sensitive to visible light, the plurality of pixels being placed in the carrier substrate, and a plurality of pixels sensitive to short-wave infrared rays, the plurality of pixels sensitive to infrared rays being placed in a surface region of the carrier substrate; and
a protective layer placed at least on the side walls of each pixel so as to electrically isolate each pixel from adjacent pixels;
wherein the plurality of pixels sensitive to visible light and the plurality of pixels sensitive to short-wave infrared rays form an arrangement placed in a same plane, and wherein the carrier substrate is a semiconductor-on-insulator substrate comprising, in succession, a base substrate of a semiconductor material, an electrically insulating intermediate layer and a single-crystal layer made of a semiconductor material.

12. The method of claim 5, wherein the second semiconductor material is a III-V semiconductor material chosen from indium phosphide or indium-gallium arsenide.

13. The method of claim 1, wherein step c comprises forming the protective layer by thermal oxidation.

14. The method of claim 1, wherein the first semiconductor material is silicon.

15. The method of claim 1, wherein the second semiconductor material is a III-V semiconductor material, a germanium alloy, or colloidal quantum dots based on lead(II) sulfide or lead selenide.

16. The method of claim 1, wherein the carrier substrate is a silicon-on-insulator substrate, and comprises in succession a base substrate, an electrically insulating intermediate layer and a single-crystal layer of the first semiconductor material.

17. The method of claim 16, further comprising, between step b and step c, a step b′ of thickening the single-crystal layer by homo-epitaxy.

18. The method of claim 16, wherein step b comprises etching the carrier substrate until the electrically insulating intermediate layer is reached.

19. The method of claim 16, further comprising, after step c, a step c″ of removing, from the cavities, the material forming the electrically insulating intermediate layer, and wherein the pixels sensitive to short-wave infrared rays are formed in step d on the face of the base substrate revealed by the removing step c″.

20. The method of claim 1, wherein the carrier substrate is a bulk substrate of the first semiconductor material.
